(19) United States
(12) Patent Application Publication
(10) Pub. No.: US 2024/0093369 A1
(43) Pub. Date: Mar. 21, 2024

(54) DEPOSITION APPARATUS

(71) Applicant: Samsung Display Co., LTD., Yongin-si (KR)

(72) Inventors: GIYUL HAM, Yongin-si (KR); SEOK-JIN KO, Yongin-si (KR); KYUNGSOO OH, Yongin-si (KR); HAKSOO LEE, Yongin-si (KR)

(21) Appl. No.: 18/224,312

(22) Filed: Jul. 20, 2023

(30) Foreign Application Priority Data
Sep. 21, 2022 (KR) 10-2022-0119613

(51) Int. Cl. C23C 16/458; C23C 16/46

(52) U.S. Cl. CPC C23C 16/4586; C23C 16/46

(57) ABSTRACT

A deposition apparatus includes a chamber providing an inner space, a gate disposed on one side of the chamber and opening and closing the chamber to allow a substrate to be loaded and unloaded therethrough, and a susceptor including one surface on which the substrate is seated. The susceptor includes a susceptor body including a first region and a second region disposed in a first direction farther away from the gate than the first region, a first hot-wire arranged in a first pattern in the first region, and a second hot-wire arranged in a second pattern in the first and second regions. The first and second hot-wires is asymmetric with respect to a second direction crossing the center of the susceptor body in a plan view and orthogonal to the first direction, and the first and second hot-wires may be controlled independently.

This application claims priority to Korean Patent Application No. 10-2022-0119613, filed on Sep. 21, 2022, and all the benefits accruing therefrom under 35 U.S.C. § 119, the content of which in its entirety is herein incorporated by reference.

### BACKGROUND

### 1. Field

The disclosure herein relates to a deposition apparatus, and more particularly, to a deposition apparatus that uniformly maintains a substrate temperature with separate hot-wires adjacent to a gate.

### 2. Description of the Related Art

In response to the integration of electronic elements, a technology for uniformly depositing a nano-scaled thin film through atomic layer deposition has been developed. As a sensitivity of a silicon nitride film process to high temperatures gradually increases, efforts to reduce process temperatures are underway, and as part of this, a low temperature process using plasma is being developed.

### SUMMARY

The disclosure provides a deposition apparatus capable of resolving a temperature non-uniformity of a substrate seated on an upper part of a susceptor.

An embodiment of the inventive concept provides a deposition apparatus which may include a chamber, a gate and a susceptor. The chamber may provide an inner space. The gate may be disposed on one side of the chamber, and open and close the chamber to allow a substrate to be loaded and unloaded therethrough. The susceptor may include one surface on which the substrate is seated. The susceptor may include a susceptor body including a first region and a second region disposed in a first direction farther away from the gate than the first region, a first hot-wire arranged in a first pattern in the first region, and a second hot-wire arranged in a second pattern in the first and second regions, and the first and second hot-wires may be asymmetric with respect to a second direction orthogonal to the first direction and crossing the center of the susceptor body in a plan view, and the first and second hot-wires may be controlled independently.

In an embodiment, the first hot-wire may include a higher heating value per unit area than that of the second hot-wire.

In an embodiment, an exhaust port adjacent to the gate may be defined on a lower surface of the chamber.

In an embodiment, a first distance from the one side of the chamber on which the gate is disposed in one side of the susceptor body adjacent to the one side of the chamber may be bigger than a second distance from another side of the chamber to another side of the susceptor body adjacent to the other side of the chamber.

In an embodiment, the second hot-wire may include at least one (2-1)-th hot-wire and at least one (2-2)-th hot-wire that are controlled independently, and the (2-1)-th hot-wire may be disposed inside the susceptor body, and the (2-2)-th hot-wire may be disposed along an edge of the susceptor body.

In an embodiment, in a plan view, the (2-1)-th hot-wire may be symmetric with respect to the first direction crossing the center of the susceptor body.

In an embodiment, in a plan view, the first hot-wire may be symmetric with respect to the first direction crossing the center of the susceptor body.

In an embodiment, in the second direction, the first hot-wire may be disposed more inside the susceptor than the second hot-wire.

In an embodiment, a portion of the first hot-wire adjacent to the gate may extend along the second direction.

In an embodiment, a maximum length of the first hot-wire along the second direction may be about 0.5 times to 1 times a length of the susceptor body along the second direction.

In an embodiment, a minimum length of a planar area of the first hot-wire along the second direction may be about 0.6 times or less than a length of the susceptor body along the second direction.

In an embodiment, a planar area of the first hot-wire may be about 0.8 times or less than a planar area of the first region.

In an embodiment, as being farther away from the gate in the first direction, the area taken by the first hot-wire may be constant or become smaller.

In an embodiment, the first hot-wire may be biased toward one side of the first region adjacent to the gate. The second hot-wire may be biased toward one side of the second region far from the gate.

In an embodiment, a maximum length of a planar area of the first hot-wire along the first direction may be about 0.5 times or more than a length of the first region along the first direction.

In an embodiment of the inventive concept, a deposition apparatus may include a susceptor including one surface on which a substrate is seated, and the susceptor may include a susceptor body including a first region and a second region that are divided with respect to a first direction crossing the center of the susceptor, a first hot-wire bent a plurality of times and disposed in the first region, and a second hot-wire bent a plurality of times and disposed in the first and second regions, and as being closer to the center of the susceptor body in a second direction crossing the first direction, an area taken by the first hot-wire may be constant or become smaller, and the first and second hot-wires may be controlled independently.

In an embodiment, the first hot-wire and the second hot-wire may be asymmetric in a plan view with respect to the first direction.

In an embodiment, the first hot-wire may be biased toward one side of the first region far from the second region.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of an embodiment of a deposition apparatus according to the inventive concept;

FIG. 2 is a view illustrating an airflow due to an exhaust port of FIG. 1;

FIG. 3 is a plan view of an embodiment of a susceptor and a gate according to the inventive concept;

FIG. 4 is a plan view of an embodiment of a susceptor according to the inventive concept;

FIG. 5 is a view illustrating a temperature distribution of a typical susceptor body;

FIG. 6 is a view illustrating a temperature distribution of the susceptor of FIG. 4;

FIG. 7 is a view numerically illustrating a temperature distribution of the susceptor body of FIG. 4;

FIG. 8 is a plan view of an embodiment of a susceptor according to the inventive concept;

FIG. 9 is a view illustrating a temperature distribution of the susceptor of FIG. 8;

FIG. 10 is a view numerically illustrating a temperature distribution of the susceptor body of FIG. 8;

FIGS. 11A to 11D are each a view illustrating a temperature distribution of a susceptor according to a shape of a first hot-wire;

FIG. 12 is a plan view of an embodiment of a susceptor according to the inventive concept; and

FIG. 13 is a view illustrating a temperature distribution of the susceptor of FIG. 12.

### DETAILED DESCRIPTION

In this specification, when an element (or region, layer, portion, etc.) is referred to as being “on”, “connected to” or “coupled to” another element, it means that it can be directly on, connected or coupled to the other element, or a third element can be disposed between them.

Like reference numerals or symbols refer to like elements. In addition, in the drawings, the thickness, the ratio and the dimension of the elements are exaggerated for effective description of the technical contents. “And/or” includes all combinations of one or more that the associated elements may define.

Although terms such as first and second may be used to describe various elements, these elements should not be limited by these terms. These terms are only used for the purpose to distinguish one element from another elements. For example, without departing from the scope of the inventive concept, a first element could be termed a second element, and similarly, a second element could be termed a first element. The singular expressions include the plural expressions unless the context clearly indicates otherwise.

In addition, terms such as “below”, “lower”, “above”, and “upper” are used to describe relationships between the elements shown in the drawings. These terms are relative concepts and are described based on the directions indicated in the drawings.

It will be understood that the terms such as “includes” and/or “including”, when used in this specification, specify the presence of stated features, integers, steps, operations, elements, components and/or, groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this inventive concept belongs. In addition, terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be explained with reference to the accompanying drawings.

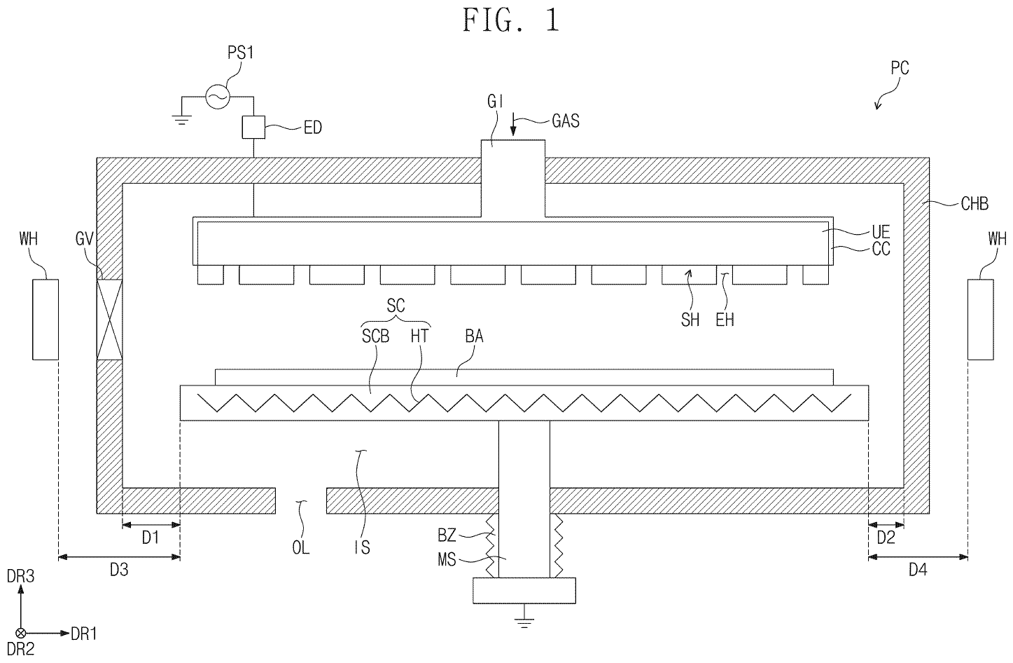

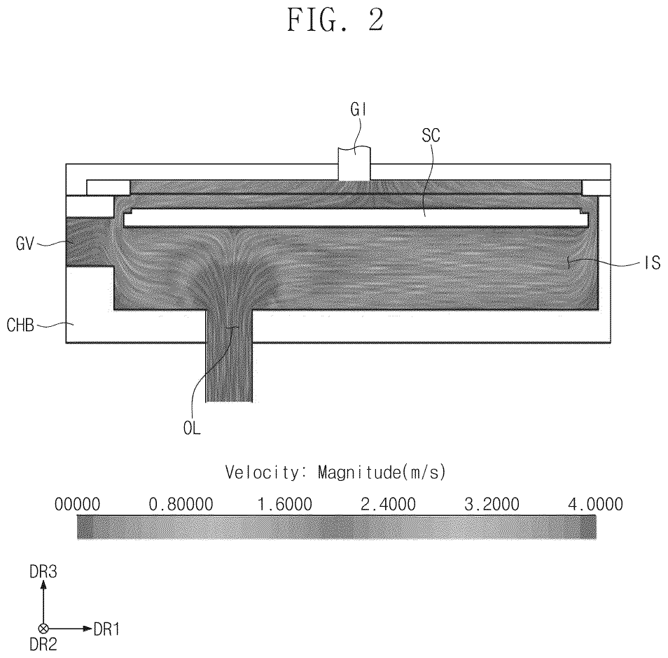

FIG. 1 is a cross-sectional view of an embodiment of a deposition apparatus PC according to the inventive concept. FIG. 2 is a view illustrating an airflow due to an exhaust port OL of the FIG. 1.

Referring to FIG. 1, the deposition apparatus PC may deposit a thin film on a substrate BA through a plasma enhanced chemical vapor deposition (“PECVD”) method that induces chemical reactions among process gas in a state in which the process gas GAS is excited into a plasma state using substantially high voltage energy.

The deposition apparatus PC may include a chamber CHB, a gate GV, an exhaust port OL, an exterior heater WH, a substrate BA, a bellows BZ, a shaft MS, a susceptor SC, a power supply device PS1, showerheads SH, an upper electrode UE, and a gas inlet GI. Here, a person with ordinary skill in the art related to this embodiment would understand that other general-purpose elements other than those illustrated in FIG. 1 may be further included in the deposition apparatus PC.

The deposition apparatus PC may include the chamber CHB that is separated from an external region and provides an inner space IS where chemical reactions occur. The gate GV, through which the substrate BA may be loaded and unloaded, and which may open and close the chamber CHB, may be disposed on one side of the chamber CHB. After the gate GV is open, the substrate BA may be loaded into the inner space IS of the chamber CHB and seated on an upper surface of the susceptor SC.

The exterior heater WH may be adjacent to an exterior surface of the chamber CHB. The exterior heater WH may prevent an internal temperature of the chamber CHB from being affected by an external temperature of the chamber CHB which is room temperature. The exhaust port OL for discharging the process gas GAS or the like may be disposed on the lower surface of the chamber CHB.

Referring to FIGS. 1 and 2, on the lower surface of the chamber CHB, the exhaust port OL may be adjacent to the gate GV. In the inner space IS, an airflow in a region adjacent to the exhaust port OL may flow rapidly, and as being farther away from the exhaust port OL, an airflow may flow more slowly. Since the exhaust port OL is adjacent to the gate GV, and thus airflows are formed asymmetrically, a heat loss occurs more actively in the vicinity of the gate GV, thereby causing a temperature drop.

The substrate BA in an embodiment of the inventive concept may be a part that constitutes a display panel. In an embodiment, the substrate BA may be a part of an organic light-emitting display panel including organic light-emitting elements, for example. However, this is merely one of embodiments, and a display panel in an embodiment of the inventive concept may include a quantum-dot display panel, a micro light-emitting diode (“LED”) display panel, or a nano LED display panel.

The substrate BA may include a surface parallel to a plane defined by a first direction DR1 and a second direction DR2. A thickness direction of the substrate BA may be indicated by a third direction DR3. A front surface (or an upper surface) and a rear surface (or a lower surface) of the substrate BA may be defined by the third direction DR3. The third direction DR3 may be a direction crossing the first direction DR1 and the second direction DR2. In an embodiment, the first direction DR1, the second direction DR2, and the third direction DR3 may be orthogonal to each other, for example. In addition, in this specification, a plane defined by the first direction DR1 and the second direction DR2 may be defined as a plane, and “in a plan view” may be defined as being viewed in the third direction DR3.

The upper electrode UE may be disposed above the substrate BA while facing the substrate BA. The upper electrode UE may include a gas inlet GI. A plurality of spray holes EH may be defined in the upper electrode UE. The upper electrode UE may include aluminum. However, a material of the upper electrode UE is not limited thereto and may include various materials. In an embodiment, the upper electrode UE may include a stainless steel, for example.

The process gas GAS may be injected into the upper electrode UE through the gas inlet GI. The injected process gas GAS may be uniformly sprayed onto an upper surface of the substrate BA through the plurality of spray holes EH.

The power supply device PS1 may be electrically connected to the upper electrode UE and the showerheads SH to supply radio frequency (“RF”) power, etc. The power supply device PS1 may be connected to a matcher ED for matching impedance.

The upper electrode UE may be electrically connected to the power supply device PS1. The upper electrode UE may supply energy desired to excite the sprayed process gas GAS. The energy may convert the process gas GAS sprayed through the plurality of spray holes EH into plasma. The process gas GAS, which has been converted into plasma, may form a thin film by repeating diffusion and desorption after adsorption on a surface of the substrate BA.

A conductive sheet CC may be disposed on a surface of the upper electrode UE. The conductive sheet CC may transmit power from the power supply device PS1 to the upper electrode UE. The conductive sheet CC may include materials having electrical conductivity and thermal conductivity.

The showerheads SH may be coupled to a lower part of the upper electrode UE and uniformly spray a gas toward the substrate BA. Since the plurality of spray holes EH is defined in the showerheads SH, the gas may be uniformly sprayed onto the substrate BA through the plurality of spray holes EH.

The susceptor SC may include a susceptor body SUB and a hot-wire HT. The susceptor SC may include one surface on which the substrate BA may be disposed (e.g., seated). The susceptor SC may support and heat the seated substrate BA. The susceptor SC may be supported by the shaft MS disposed below the susceptor SC. The shaft MS may be surround by the bellows BZ surrounding an outer periphery of the shaft MS. The bellows BZ may protect the shaft MS from an external impact and seal the shaft MS.

Since the susceptor SC functions as a counter electrode of the upper electrode UE which is a plasma electrode, the susceptor SC and the upper electrode UE may face each other. The susceptor SC may be grounded through the shaft MS. That is, a current of the susceptor SC may be discharged through the shaft MS.

The substrate BA is loaded onto the upper surface of the susceptor SC, and thereafter, when applying the RF power to the upper electrode UE while spraying the process gas GAS toward the substrate BA through the showerheads SH, plasma may be generated between the upper electrode UE and the susceptor SC, and the process gas GAS may be excited by the plasma. Since molecules of the excited gas are deposited onto the substrate BA at a predetermined temperature, a thin film may be formed on the substrate BA.

The susceptor body SUB may be disposed (e.g., mounted) inside the chamber CHB and may have a plate shape extending along the plane defined by the first direction DR1 and the second direction DR2.

A hot-wire HT for controlling the temperature of the substrate BA may be installed inside the susceptor SC. A flow path for supplying a backside gas, e.g., helium gas, may be installed inside the susceptor SC to efficiently transfer the temperature of the susceptor SC to the substrate BA. The susceptor SC may include a metal. In an embodiment, the susceptor SC may include aluminum, for example.

With respect to the susceptor SC, a first distance D1, which is a distance from one side on which the gate GV is disposed among sides of the chamber CHB, may be greater than a second distance D2, which is a distance from the other side, on which the gate GV is not disposed among the sides of the chamber CHB. Therefore, the susceptor SC may be spaced apart from the gate GV connected to the external environment having a temperature lower than the internal temperature of the chamber CHB, and influences due to an external temperature may be minimized. Accordingly, the distance D3 between the side of the susceptor SC adjacent to the gate GV and the external heater WH may be greater than the distance D4 between the side of the susceptor SC far from the gate GV and the external heater WH.

As such, the susceptor SC may serve as a substrate table that stably supports the substrate BA during a deposition process, and for a uniform and reliable process progress, the hot-wire HT may generate heat to control the temperature of the substrate BA.

The hot-wire HT may be disposed inside the susceptor body SUB. The hot-wire HT may provide heat to the substrate BA. In the process of depositing a thin film, the hot-wire HT may heat the substrate BA to a temperature suitable for deposition. At such a temperature, the process gas GAS, which has been converted into plasma, may be easily diffused in the substrate BA, and the process gas GAS, which has been converted into plasma, may be settled in a stable bonding structure.

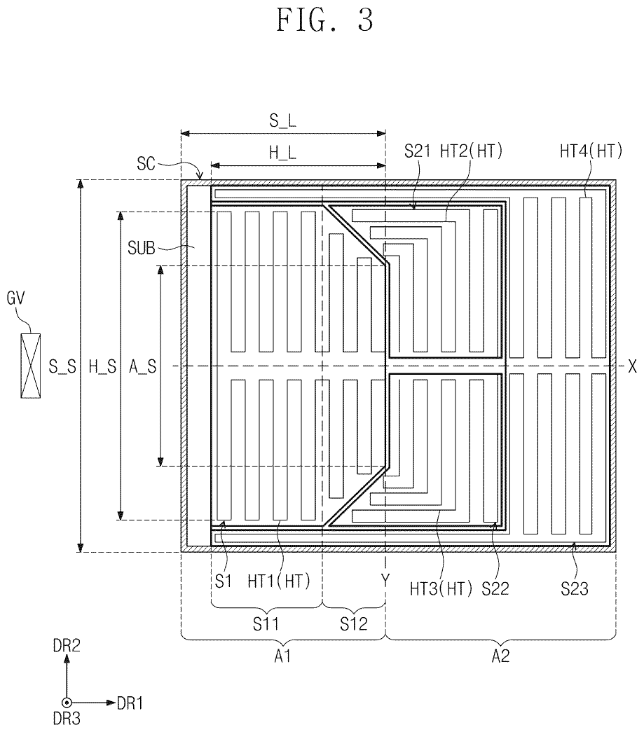

FIG. 3 is a plan view of an embodiment of a susceptor SC and a gate GV according to the inventive concept.

Referring to FIG. 3, the susceptor SC may include a susceptor body SUB, a first hot-wire HT1, a second hot-wire HT2, a third hot-wire HT3, and a fourth hot-wire HT4. However, hot-wires of the susceptor SC are not limited to the first hot-wire to the fourth hot-wire HT1 to HT4, and additional hot-wires may be provided as desired.

The susceptor body SUB may include a first region A1 adjacent to the gate GV and a second region A2 farther away from the gate GV than the first region A1.

The first hot-wire HT1 may be arranged in a first pattern in the first region A1. The first hot-wire HT1 may be bent a plurality of times and disposed in the first region A1 with a uniform density. However, the density and the pattern of the first hot-wire HT1 are not limited thereto and the first hot-wire HT1 may be disposed with various densities and in various patterns. A planar area where the first hot-wire HT1 is disposed may be defined as a first heating region S1.

The first hot-wire HT1 may have a higher heating value per unit area than the second to fourth hot-wires HT2 to HT4. Since the first heating region S1, in which the first hot-wire HT1 is disposed, is adjacent to the gate GV and overlays the exhaust port OL (refer to FIG. 2), the temperature of the first heating region S1 may be relatively low due to a heat exchange with the outside and a heat loss due to a rapid airflow. In addition, a distance to the exterior heater WH is far so that a temperature drop may occur. Therefore, the temperature of the susceptor SC may be uniformly maintained by maintaining the heating value per unit area of the first hot-wire HT1 to be higher than that of the second to fourth hot-wires HT2 to HT4.

The first hot-wire HT1 may be controlled independently from the second to fourth hot-wires HT2 to HT4 to be described later. In the first heating region S1 in which the first hot-wire HT1 is disposed, temperature tends to be maintained relatively low unlike other regions, and thus needs to be controlled independently from the other regions.

The first hot-wire HT1 has a higher heating value per unit area than those of the second to fourth hot-wires HT2 to HT4, and therefore, when the first heating region S1 is disposed in a low-temperature region of the susceptor body SUB, the temperature of the susceptor body SUB may become uniform.

Referring to FIGS. 1 and 3, the first hot-wire HT1 may be symmetric with respect to an X-axis X which crosses the center of the susceptor body SUB and is parallel to the first direction DR1. A factor that mainly affects the temperature of the susceptor SC may be a distance from the gate GV and the exhaust port OL (refer to FIG. 1). Since the gate GV and the exhaust port OL (refer to FIG. 1) are disposed only on a left side with respect to a Y-axis Y, the distances from the gate GV and the exhaust port OL may greatly vary in the susceptor body SUB along the first direction DR1. Therefore, a temperature gradient of the susceptor body SUB may become relatively large along the first direction DR1 and relatively small along the second direction DR2.

When the centers of the gate GV and the exhaust port OL (refer to FIG. 1) are disposed on the X-axis X, the distances from the gate GV and the exhaust port OL may be vertically symmetric with respect to the X-axis X. Accordingly, the temperature distribution of the susceptor body SUB may be approximately symmetric with respect to the X-axis X. The first hot-wire HT1 which resolves the temperature non-uniformity of the susceptor body SUB may have a symmetric shape with respect to the X-axis X parallel to the first direction DR1.

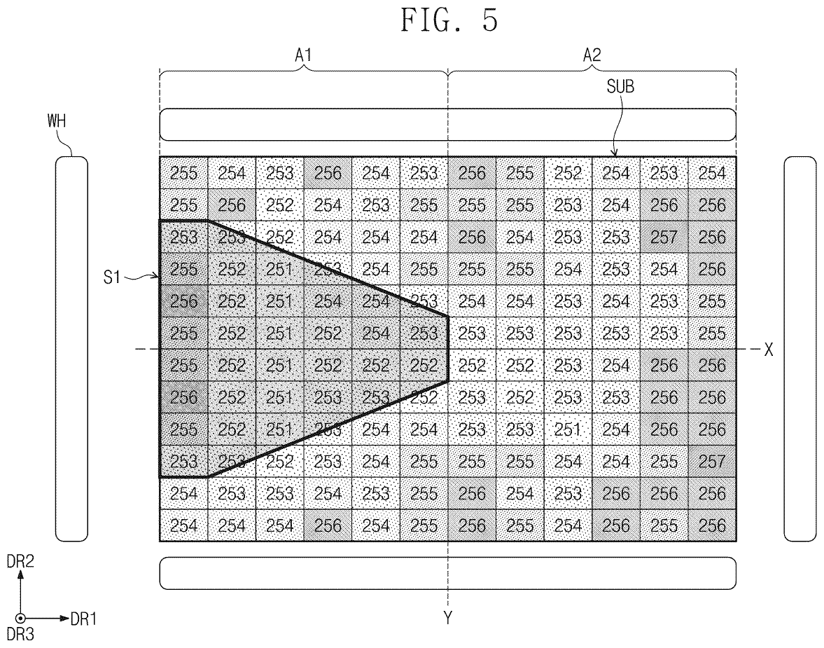

A straight portion of the first hot-wire HT1 adjacent to the gate GV may extend along the second direction DR2. This is because, in the susceptor body SUB, one side of a region, which has a relatively low temperature due to influences of the gate GV and the exhaust port OL, is parallel to the second direction DR2. A detailed temperature gradient of the susceptor body SUB will be described later with reference to FIGS. 5 to 7.

A maximum length H_S (hereinafter, a first hot-wire length) of the first hot-wire HT1 along the second direction DR2 may be about 0.5 times to 1 times a length S_S of the susceptor body SUB along the second direction DR2. When the first hot-wire length H_S is smaller than about 0.5 times the length S_S of the susceptor body SUB along the second direction DR2, a low-temperature region of the susceptor body SUB may not be sufficiently covered. When the first hot-wire length H_S has a length greater than about 1 times the length S_S of the susceptor body SUB along the second direction DR2, the first hot-wire HT1 may protrude to the outside of the susceptor body SUB and the first hot-wire HT1 may be damaged by high-temperature plasma during a deposition process.

A minimum length A_S (hereinafter, a first heating region minimum length), along the second direction DR2, of the first heating region S1 which is a planar area taken by the first hot-wire HT may be smaller than about 0.6 times the length S_S of the susceptor body SUB along the second direction DR2. When the first heating region minimum length A_S is greater than about 0.6 times the length S_S of the susceptor body SUB along the second direction DR2, the first heating region S1 may affect even a region where temperature is not relatively low and thus a separate temperature control is not desired. In addition, the temperature of an edge portion of the susceptor body SUB, which is adjacent to the exterior heater WH and thus has relatively high temperature, may be increased, thereby causing the temperature of the susceptor body SUB may to become non-uniform.

An area of the first heating region S1 may be within about 0.8 times a planar area taken by the first region A1. The first heating region S1 needs to cover only a region that is adjacent to the gate GV to be heat-exchanged with the outside and is spaced apart from the exterior heater WH to have a decreased temperature. When the area of the first heating region S1 is greater than about 0.8 times the planar area taken by the first region A1, not only a low-temperature region but also a high-temperature region in the susceptor body SUB becomes included in the first heating region S1, and thus the temperature of the susceptor body SUB may become non-uniform. The area of the first heating region S1 may be preferably about 0.4 times to about 0.6 times the planar area taken by the first region A1.

As the first hot-wire HT1 is farther away from the gate GV in the first direction DR1, the area taken by the first hot-wire HT1 may be uniform or become smaller. This is because as the first hot-wire HT1 is closer to the gate GV, a heat exchange with the outside having relatively low temperature occurs more actively, resulting in an increase in the low-temperature region in the susceptor body SUB.

The first heating region S1 may include a constant region S11 and a variable region S12. In the constant region S11, even as the first hot-wire HT1 is farther away from the gate GV in the first direction DR1, the area taken by the first hot-wire HT1 may become constant. In the variable region S12, as the first hot-wire HT1 is farther away from the gate GV in the first direction DR1, the area taken by the first hot-wire HT1 may become smaller.

The constant region S11 may be more adjacent to the gate GV than the variable region S12. Since a relatively large amount of heat needs to be provided to a region adjacent to the gate GV, the region adjacent to the gate GV may receive a relatively large amount of heat from the first hot-wire HT1 by maintaining the area taken by the first hot-wire HT1.

The first hot-wire HT1 may be biased toward one side of the first region A1 adjacent to the gate GV. To prevent the temperature of the susceptor body SUB adjacent to the gate GV from decreasing due to a heat loss by the gate GV, the first hot-wire HT1 may be biased toward the one side of the first region A1 adjacent to the gate GV. Since the second hot-wire HT2 to be described later is biased toward one side of the second region A2 which is far from the gate GV, the density of the first hot-wire HT1 may become greater as being closer to the gate GV.

A maximum length H_L of the first heating region S1 along the first direction DR1 may be greater than about 0.5 times a length S_L of the first region A1 along the first direction DR1. When the maximum length H_L of the first heating region S1 along the first direction DR1 is smaller than about 0.5 times the length S_L of the first region A1 along the first direction DR1, the low-temperature region of the susceptor body SUB may not be sufficiently covered. This will be described later with reference to FIGS. 5 to 7.

The second to fourth hot-wires HT2 to HT4 may be arranged in a second pattern in the first region A1 and the second region A2. The second to fourth hot-wires HT2 to HT4 may be bent a plurality of times and disposed in the first region A1 and the second region A2 with a uniform density. However, the density and the pattern of the second to fourth hot-wires HT2 to HT4 are not limited thereto and the second to fourth hot-wires HT2 to HT4 may be disposed with various densities and in various patterns. A planar area where the second to fourth hot-wires HT2 to HT4 are disposed is defined as a second heating region S2.

The second hot-wire HT2 may be adjacent to the first heating region S1 and more adjacent to an inside of the susceptor body SUB than a (2-3)-th heating region S23 to be described later. A planar area where the second hot-wire HT2 is disposed is defined as a (2-1)-th heating region S21.

The third hot-wire HT3 may be adjacent to the first heating region S1 and more adjacent to the inside of the susceptor body SUB than the (2-3)-th heating region S23. A planar area where the third hot-wire HT3 is disposed is defined as a (2-2)-th heating region S22. The (2-2)-th heating region S22 may be disposed on a lower portion of the (2-1)-th heating region S21. In an embodiment, the second hot-wire HT2 and the third hot-wire HT3 may be also referred to as a (2-1)-th hot-wire.

The second hot-wire HT2 and the third hot-wire HT3 may be controlled independently as desired and symmetric with respect to the first direction DR1 crossing the center of the susceptor body SUB.

The fourth hot-wire HT4 may be adjacent to the (2-1)-th heating region S21 and the (2-2)-th heating region S22, and closer to an edge of the susceptor body SUB than the (2-3)-th heating region S23. The fourth hot-wire HT4 may be disposed along the edge of the susceptor body SUB. A planar area where the fourth hot-wire HT4 is disposed is defined as a (2-3)-th heating region S23. The (2-3)-th heating region S23 may surround the (2-1)-th heating region S21 and the (2-2)-th heating region S22. In an embodiment, the fourth hot-wire HT4 may be also referred to as a (2-2)-th hot-wire.

The fourth hot-wire HT4 may be controlled independently from the second hot-wire HT2 and the third hot-wire HT3. The inside and the edge of the susceptor body SUB have a relatively large difference in a distance to the exterior heater WH and thus have a relatively large temperature gradient (refer to FIG. 5). Therefore, it is desired to reduce the temperature gradient by independently controlling the second hot-wire HT2 and the third hot-wire HT3 disposed on the inside of the susceptor body SUB from the fourth hot-wire HT disposed on the edge of the susceptor body SUB.

An arrangement of the first to fourth hot-wires HT1 to HT4 may be symmetric with respect to the first direction crossing the center of the susceptor body SUB. The arrangement of the first to fourth hot-wires HT1 to HT4 may be asymmetric with respect to the second direction DR2 crossing the center of the susceptor body SUB. That is, the arrangement of the first to fourth hot-wires HT1 to HT4 may have different shapes with respect to the second direction DR2. Since a distance to the gate GV and a distance to the exhaust port OL (refer to FIG. 1) are asymmetric in the first direction DR1, the temperature of the susceptor body SUB may also be asymmetric in the first direction DR1. Therefore, the first to fourth hot-wires HT1 to HT4 that control the temperature of the susceptor body SUB may be arranged in different shapes along the first direction DR1 and asymmetric with respect to the second direction DR2.

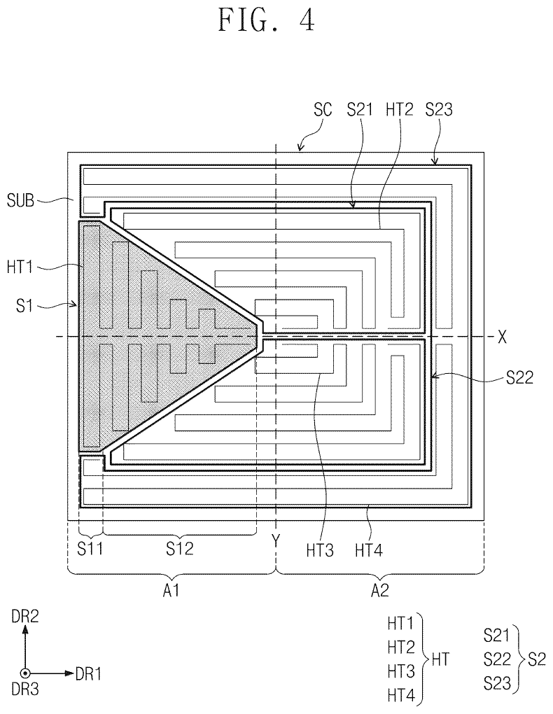

FIG. 4 is a plan view of an embodiment of a susceptor SC according to the inventive concept.

As illustrated in FIG. 4, a first heating region S1 and a second heating region S2 in an embodiment of the inventive concept may be changed depending on a temperature gradient of the susceptor SC within a range that meets the conditions described above.

A length of the first heating region S1 along the second direction DR2 may become smaller toward the center of the susceptor body SUB along the first direction DR1. On a plane, the first heating region S1 may have a triangular shape with one side in parallel with one side of the susceptor body SUB adjacent to the gate GV (refer to FIG. 1).

In the second direction DR2, the first hot-wire HT1 may be disposed in the susceptor body SUB more inwards than the second hot-wire HT2. Accordingly, a temperature uniformity of the susceptor SC may be improved by independently controlling the temperature of the inside of the susceptor SC where the temperature tends to become low.

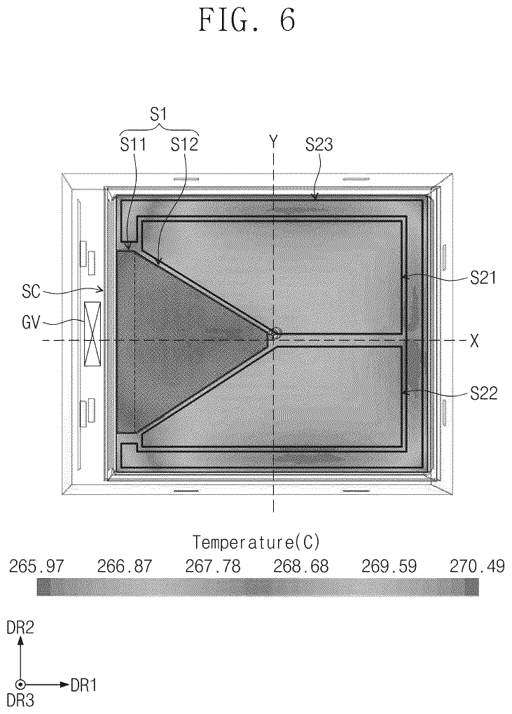

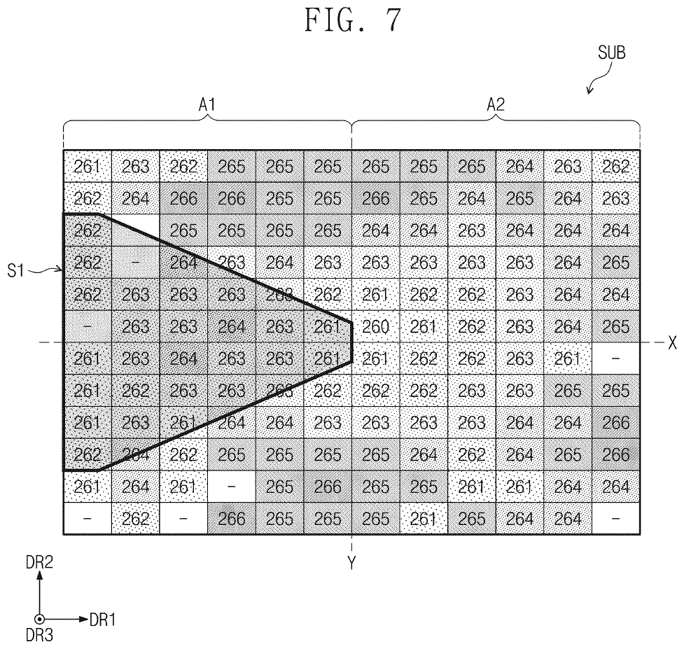

FIG. 5 is a view illustrating a temperature distribution of a typical susceptor body SUB, and FIG. 6 is a view illustrating a temperature distribution of the susceptor SC of FIG. 4, and FIG. 7 is a view numerically illustrating a temperature distribution of the susceptor body SUB of FIG. 4.

Referring to FIG. 5, the temperature distribution of the typical susceptor body SUB may be seen. FIG. 5 is a view numerically illustrating the temperature distribution when hot-wires are arranged with the same density throughout the susceptor body SUB. An edge of the susceptor body SUB is adjacent to the exterior heater WH, and may thus have a higher temperature than the inside of the susceptor body SUB.

An average temperature of the susceptor body SUB corresponding to the first region A1 may be about 253.42 degrees Celsius (° C.). An average temperature of the susceptor body SUB corresponding to the second region A2 may be about 254.36° C. A difference between the average temperature of the first region A1 and the average temperature of the second region A2 may be about 0.94° C. Heat supplied to the first region A1 may be relatively small since the first region A1 has a great distance from the exterior heater WH adjacent to a side surface.

An average temperature of a region of the susceptor body SUB corresponding to the first heating region S1 may be about 252.9° C., which is about 1.5° C. lower than the average temperature of the susceptor body SUB in the second region A2. Such a temperature non-uniformity may make it difficult for the process gas GAS, which has been converted into plasma in the substrate BA, to settle in a stable bonding structure. In addition, deposition may not be performed uniformly over an entirety of the area of the substrate BA.

Referring to FIGS. 6 and 7, temperature distributions of a susceptor SC and a susceptor body SUB in an embodiment of the inventive concept may be seen. Referring to FIG. 6, the temperature of the susceptor SC corresponding to the first heating region S1 is not relatively low compared to those of other regions. Referring to FIG. 7, an average temperature of the susceptor body SUB corresponding to the first region A1 is about 263.33° C., and an average temperature of the susceptor body SUB corresponding to the second region A2 is about 263.47° C. A difference between the average temperature of the first region A1 and the average temperature of the second region A2 is about 0.14° C., which is lower than about 0.94° C. in the case of FIG. 5, and thus it may be seen that a temperature uniformity of the susceptor body SUB is increased.

Among 72 cells of the first region A1, the first heating region S1 takes 28 cells, and an area of the first heating region S1 may take about 39% of a planar area of the first region A1. In addition, an average temperature of the susceptor body SUB in the first heating region S1 is about 262.43° C., which may be about 1° C. lower than the average temperature of the susceptor body SUB in the second region A2. This average temperature difference is lower than the average temperature difference of 1.5° C. in the case of FIG. 5, and thus it may be seen that the temperature uniformity of the susceptor body SUB is increased.

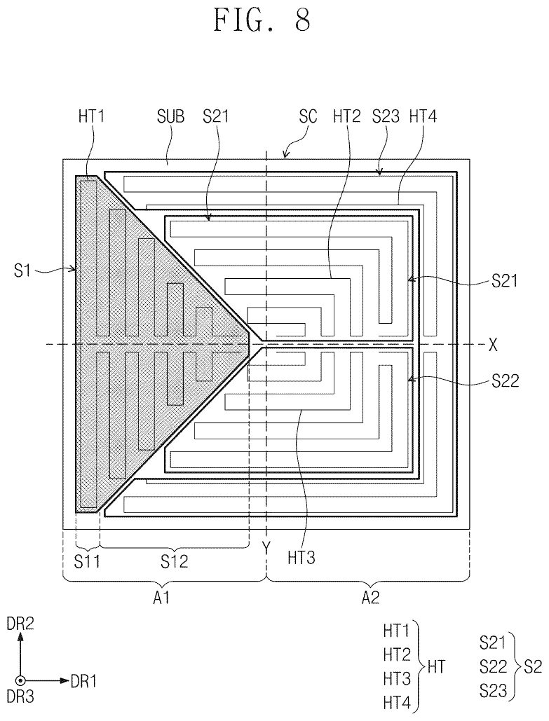

FIG. 8 is a plan view of an embodiment of a susceptor SC according to the inventive concept.

As illustrated in FIG. 8, a first heating region S1 and a second heating region S2 in an embodiment of the inventive concept may be changed depending on a temperature gradient of the susceptor SC within a range that meets the conditions described above.

The first heating region S1 of FIG. 8 may have a shape more extending in the second direction DR2 than the first heating region S1 of FIG. 4. The first heating region S1 as illustrated in FIG. 8 may be used when a heat loss effect due to the gate GV and the exhaust port OL is so great that a temperature non-uniformity between the first region A1 and the second region A2 is severe.

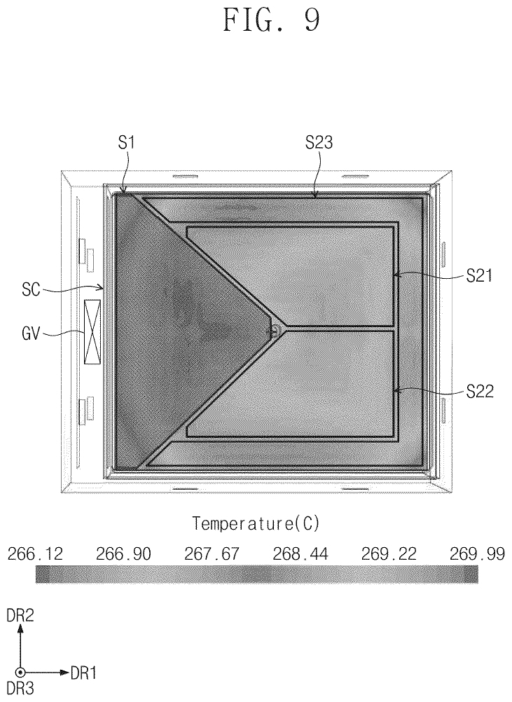

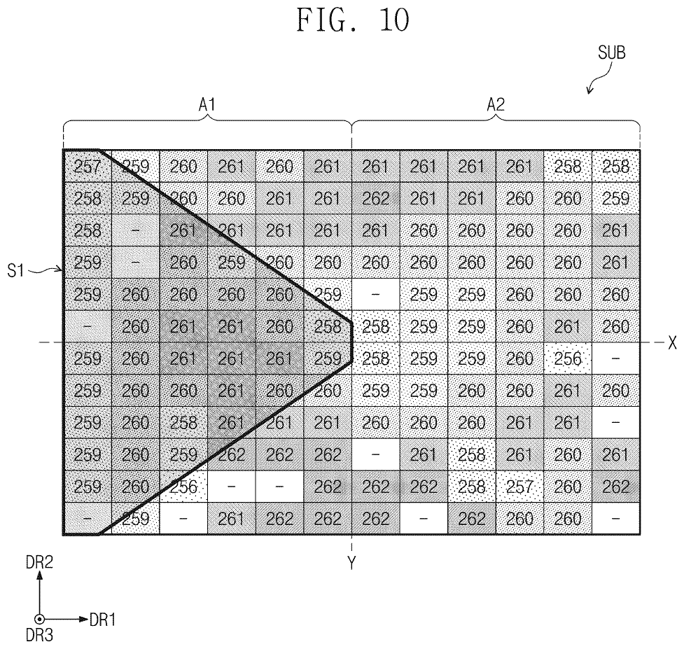

FIG. 9 is a view illustrating a temperature distribution of the susceptor SC of FIG. 8, and FIG. 10 is a view numerically illustrating a temperature distribution of the susceptor body SUB.

Referring to FIGS. 9 and 10, temperature distributions of the susceptor SC and the susceptor body SUB in an embodiment of the inventive concept may be seen. Referring to FIG. 9, it may be seen that the temperature of an area corresponding to the first heating region S1 is increased. Referring to FIG. 10, an average temperature of the susceptor body SUB corresponding to the first region A1 is about 260.02° C. and an average temperature of the susceptor body SUB corresponding to the second region A2 is about 260.03° C. A difference between the average temperature of the first region A1 and the average temperature of the second region A2 is about 0.01° C., which is lower than 0.94° C. in the case of FIG. 5 and 0.14° C. in the case of FIG. 7, and thus it may be seen that a temperature uniformity of the susceptor body SUB is increased.

Among 72 cells of the first region A1, the first heating region S1 takes 38 cells, and the first heating region S1 may take an area of about 39% of a planar area of the first region A1. In addition, an average temperature of the susceptor body SUB in the first heating region S1 is about 259.63° C., which is about 0.4° C. lower than the average temperature of the susceptor body SUB in the second region A2. This average temperature difference is lower than the average temperature difference of 1.5° C. in the case of FIG. 5 and the average temperature difference of 1° C. in the case of FIG. 7, and thus it may be seen that a temperature uniformity of the susceptor body SUB is increased.

In FIG. 10, the temperature uniformity of the susceptor body SUB was the greatest, and in this case, the first heating region S1 was about 53% of the planar area taken by the first region A1.

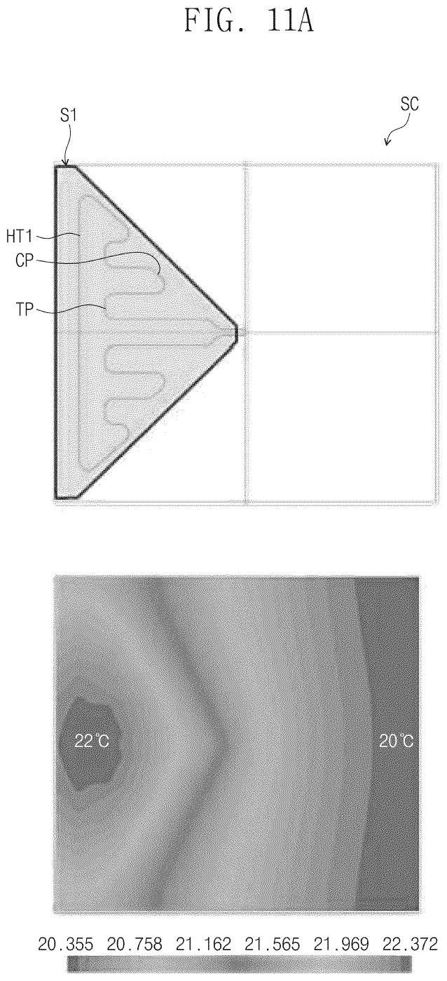

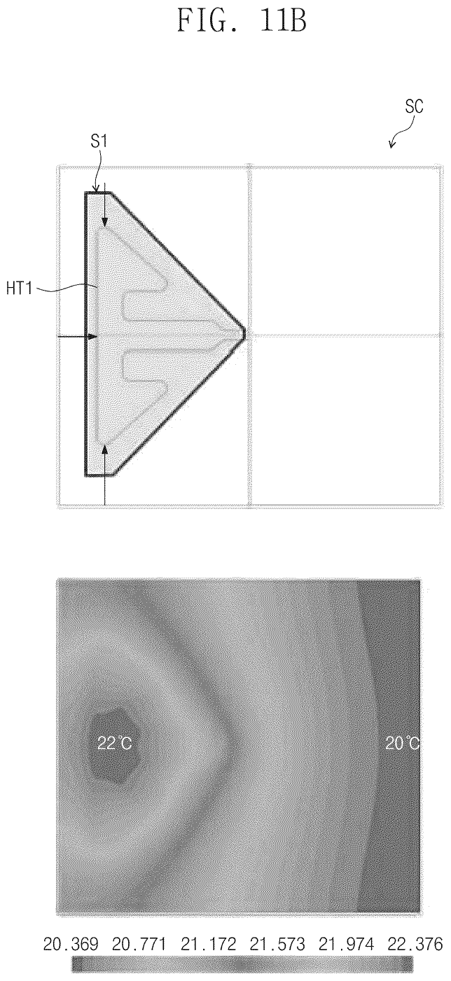

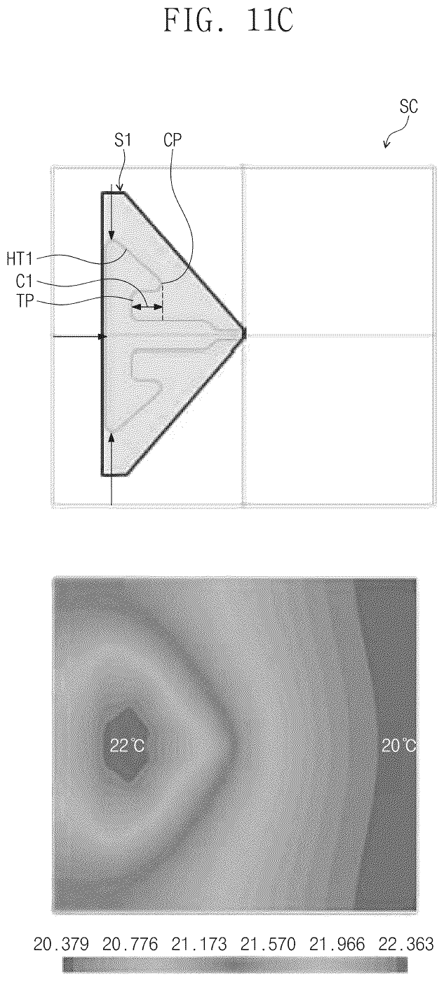

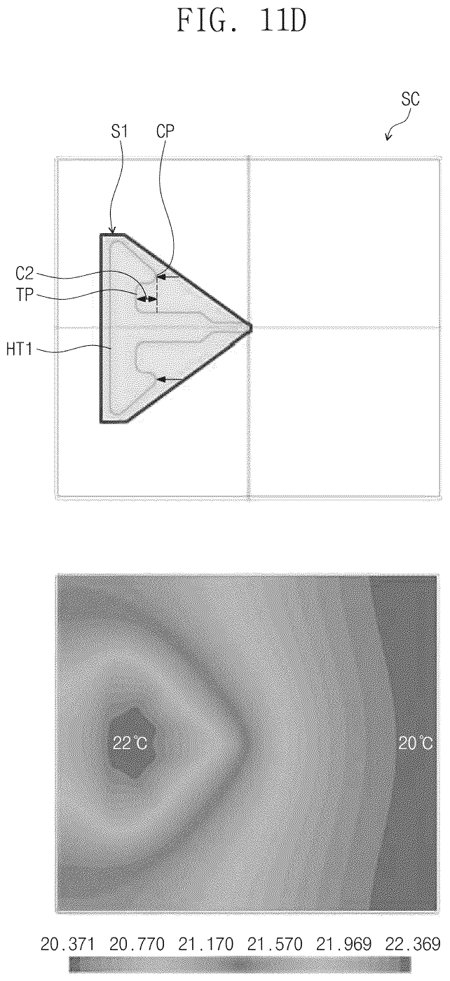

FIGS. 11A to 11D are views illustrating a temperature distribution of a susceptor SC depending on a shape of the first hot-wire HT1.

Referring to FIGS. 11A to 11D, it may be seen that a pattern of the first hot-wire HT1 and the resulting effect on the temperature of the susceptor SC may vary according to factors such as the size of the chamber CHB, the location of the exhaust port OL, the number and a location of the exterior heaters WH.

Referring to FIG. 11A, a first hot-wire HT1 may include a straight portion, extending in a straight line, on a left side thereof, and a bent portion bent multiple times on a right side thereof, the bent portion including a ridge CP protruding rightwards and a recessed valley TP. The first hot-wire HT1 may form a plurality of ridges CP and a plurality of valleys TP and be evenly distributed over an entirety of the area of the first heating region S1 to supply heat.

Referring to FIG. 11B, compared to the first hot-wire HT1 in FIG. 11A, a first hot-wire HT1 may include a left-side straight portion shifting to the right and having a decreased length. In addition, the ridge CP and the valley TP may become smaller. Referring to FIG. 11C, compared to the first hot-wire HT1 in FIG. 11B, a first hot-wire HT1 may include a left-side straight portion shifting to the right and having a decreased length. Referring to FIG. 11D, a distance C2 between the ridge CP and the valley TP may become smaller than a distance C1 between the ridge CP and the valley TP in FIG. 11C. As illustrated in FIGS. 11A to 11D, a pattern of the first hot-wire HT1 may be set differently depending on a range of the low-temperature region of the susceptor SC.

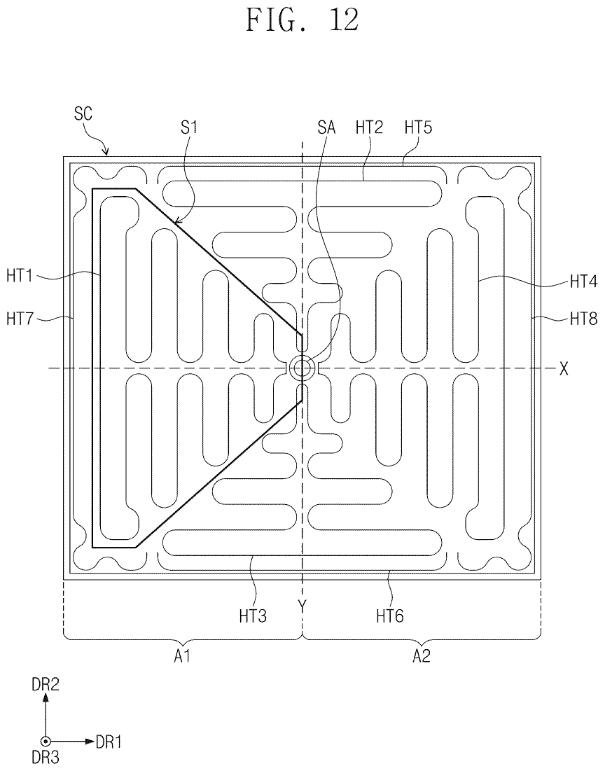

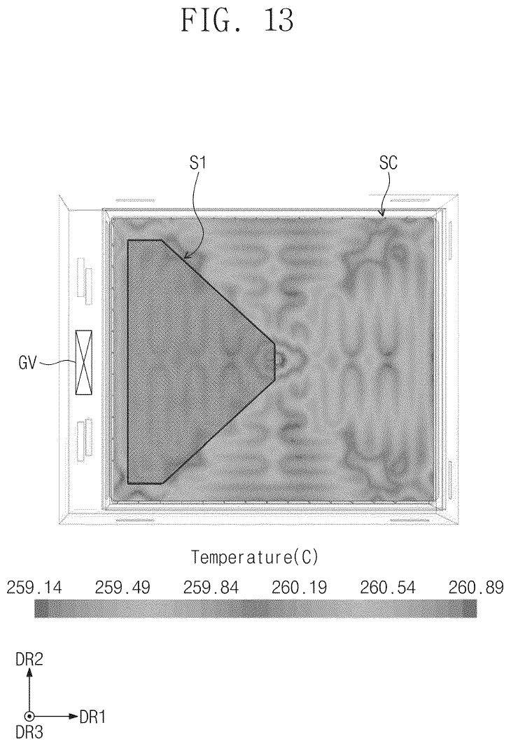

FIG. 12 is a plan view of an embodiment of a susceptor SC according to the inventive concept, and FIG. 13 is a view illustrating a temperature distribution of the susceptor SC of FIG. 12.

Referring to FIG. 12, fifth to eighth hot-wires HT5 to HT8 may be further included in addition to the first hot-wire HT1 to the fourth hot-wire HT4. The first hot-wire HT1 and the first heating region S1, which is the planar area taken by the first hot-wire HT1, may be changed within a range that meets the conditions described above. The first to eighth hot-wires HT1 to HT8 may be controlled independently. The second to eighth hot-wires HT2 to HT8 may be disposed in various ways depending on the temperature gradient of the susceptor SC to control the temperature of the susceptor SC more precisely.

The second to fourth hot-wires HT2 to HT4 may be bent a plurality of times, and disposed such that an area taken by the second to fourth hot-wires HT2 to HT4 increases from the center SA toward the edge of the susceptor SC. To independently control the temperature of the edge portion of the susceptor SC from the temperature of the inside of the susceptor SC, the fifth to eighth hot-wires HT5 to HT8 may extend in a direction in parallel with the edge of the susceptor SC. Respective ends of the seventh hot-wire HT7 and the eighth hot-wire HT8 may be bent toward the first direction DR1.

Referring to FIG. 13, when the first to eighth hot-wires HT1 to HT8 are disposed as illustrated in FIG. 12, it may be seen that a temperature drop in the vicinity of the gate GV is prevented. That is, it may be seen that the temperature of the susceptor SC is maintained uniformly over the entirety of the area.

As described above, the temperature of a substrate may be uniformly maintained by independently operating a first hot-wire disposed in a first region adjacent to a gate and a second hot-wire disposed in a second region far from the gate.

In addition, a first hot-wire is disposed considering that temperature is likely to be lower as being more adjacent to the gate, and it is thus possible to effectively respond to a temperature change.

Although the above has been described with reference to preferable embodiments of the inventive concept, a person with ordinary skill in the art would understand that various changes and modifications of the inventive concept may be made without departing from the spirit and the technical scope of the inventive concept as claimed hereinafter. Therefore, the technical scope of the inventive concept is not limited to the content described in the detailed description of this specification but should be defined by the claims.

What is claimed is:

1. A deposition apparatus, comprising:
a chamber which provides an inner space;
a gate which is disposed on one side of the chamber and opens and closes the chamber through which a substrate is loaded and unloaded; and
a susceptor including one surface on which the substrate is seated, the susceptor including:
a susceptor body including a first region and a second region disposed in a first direction farther away from the gate than the first region;
a first hot-wire arranged in a first pattern in the first region; and
a second hot-wire arranged in a second pattern in the first and second regions,
wherein the first and second hot-wires are asymmetric with respect to a second direction orthogonal to the first direction and crossing the center of the susceptor body in a plan view, and
the first and second hot-wires are controlled independently.

2. The deposition apparatus of claim 1, wherein the first hot-wire has a higher heating value per unit area than that of the second hot-wire.

3. The deposition apparatus of claim 1, wherein an exhaust port adjacent to the gate is defined on a lower surface of the chamber.

4. The deposition apparatus of claim 1, wherein a first distance from the one side of the chamber on which the gate is disposed in one side of the susceptor body adjacent to the one side of the chamber is bigger than a second distance from another side of the chamber to another side of the susceptor body adjacent to the other side of the chamber.

5. The deposition apparatus of claim 1, wherein
the second hot-wire comprises at least one (2-1)-th hot-wire and at least one (2-2)-th hot-wire which are controlled independently,
the (2-1)-th hot-wire is disposed inside the susceptor body, and
the (2-2)-th hot-wire is disposed along an edge of the susceptor body.

6. The deposition apparatus of claim 5, wherein in a plan view, the (2-1)-th hot-wire is symmetric with respect to the first direction crossing the center of the susceptor body.

7. The deposition apparatus of claim 1, wherein in a plan view, the first hot-wire is symmetric with respect to the first direction crossing the center of the susceptor body.

8. The deposition apparatus of claim 1, wherein in the second direction, the first hot-wire is disposed more inside the susceptor than the second hot-wire.

9. The deposition apparatus of claim 1, wherein a portion of the first hot-wire adjacent to the gate extends along the second direction.

10. The deposition apparatus of claim 1, wherein a maximum length of the first hot-wire along the second direction is about 0.5 times to about 1 times a length of the susceptor body along the second direction.

11. The deposition apparatus of claim 1, wherein a minimum length of a planar area of the first hot-wire along the second direction is about 0.6 times or less than a length of the susceptor body along the second direction.

12. The deposition apparatus of claim 1, wherein a planar area of the first hot-wire is about 0.8 times or less than a planar area of the first region.

13. The deposition apparatus of claim 1, wherein as being farther away from the gate in the first direction, the area taken by the first hot-wire is constant or becomes smaller.

14. The deposition apparatus of claim 1, wherein the first hot-wire is biased toward one side of the first region adjacent to the gate, and the second hot-wire is biased toward one side of the second region far from the gate.

15. The deposition apparatus of claim 1, wherein a maximum length of a planar area of the first hot-wire along the first direction is about 0.5 times or more than a length of the first region along the first direction.

16. A deposition apparatus, comprising
a susceptor including one surface on which a substrate is seated, the susceptor including:
a susceptor body including a first region and a second region which are divided with respect to a first direction crossing the center of the susceptor;
a first hot-wire bent a plurality of times and disposed in the first region; and
a second hot-wire bent a plurality of times and disposed in the first and second regions,
wherein
in a second direction crossing the first direction, an area taken by the first hot-wire is constant or becomes smaller, as being closer to the center of the susceptor body, and
the first and second hot-wires are controlled independently.

17. The deposition apparatus of claim 16, wherein the first hot-wire and the second hot-wire are asymmetric in a plan view with respect to the first direction.

18. The deposition apparatus of claim 16, wherein the first hot-wire is biased toward one side of the first region far from the second region.
